(19) United States
(12) Patent Application Publication
(10) Pub. No.: US 2024/0222401 A1
(43) Pub. Date: Jul. 4, 2024

(54) SEMICONDUCTOR DEVICE, IMAGE SENSOR

(71) Applicant: SAMSUNG ELECTRONICS CO., LTD., Suwon-si (KR)

(72) Inventors: Je-Hyung Ryu, Suwon-si (KR); Hajin Lim, Suwon-si (KR); Taeksoo Jeon, Suwon-si (KR)

(73) Assignee: SAMSUNG ELECTRONICS CO., LTD., Suwon-si (KR)

(21) Appl. No.: 18/231,445

(22) Filed: Aug. 8, 2023

(30) Foreign Application Priority Data
Jan. 4, 2023 (KR) 10-2023-0001400

(51) Int. Cl. H01L 27/146; H01L 29/423

(52) U.S. Cl. CPC H01L 27/14614; H01L 29/4238

(57) ABSTRACT

A semiconductor device and an image sensor are disclosed. The semiconductor device includes: a gate pattern disposed on a substrate; a first interlayer insulating layer on a sidewall of the gate pattern; a second interlayer insulating layer on the gate pattern and the first interlayer insulating layer; and a first contact plug passing through the second interlayer insulating layer and the first interlayer insulating layer and being in contact with the substrate, where the first contact plug comprises a first contact part in the first interlayer insulating layer and a second contact part in the second interlayer insulating layer, a density of the first interlayer insulating layer is smaller than a density of the second interlayer insulating layer, the first contact part of the first contact plug has a first width, and the second contact part of the first contact plug has a second width smaller than the first width.

### CROSS-REFERENCE TO RELATED APPLICATIONS

This U.S. non-provisional patent application claims priority under 35 U.S.C. § 119 to Korean Patent Application No. 10-2023-0001400, filed on Jan. 4, 2023 in the Korean Intellectual Property Office, the disclosure of which is incorporated herein in its entirety by reference.

### BACKGROUND

The present disclosure relates to a semiconductor device, an image sensor, and a method of fabricating the same.

An image sensor is a semiconductor device to convert optical images into electrical signals. The image sensor may be classified into a charge coupled device (CCD) type and a complementary metal oxide semiconductor (CMOS) type. The CMOS type image sensor is abbreviated to CIS (CMOS image sensor). The CIS has a plurality of two-dimensionally arranged pixels. Each of the pixels includes a photodiode. The photodiode serves to convert incident light into electrical signals. However, existing image sensors have problems with parasitic capacitance between components, thereby causing signal interference. Furthermore, existing image sensors have problems with contact resistance between components, thereby reducing signal transmission speed and a driving voltage.

### SUMMARY

An object of the present disclosure is to provide a highly integrated image sensor with improved characteristics.

An object of the present disclosure is to provide a method of fabricating a highly integrated image sensor with improved characteristics.

An object of the present disclosure is to provide a semiconductor device with improved characteristics.

The problem to be solved by the present disclosure is not limited to the problems mentioned above, and other problems not mentioned will be clearly understood by those skilled in the art from the description below.

According to one or more embodiments, a semiconductor device comprising: a gate pattern disposed on a substrate; a first interlayer insulating layer on a sidewall of the gate pattern; a second interlayer insulating layer on the gate pattern and the first interlayer insulating layer; and a first contact plug passing through the second interlayer insulating layer and the first interlayer insulating layer and being in contact with the substrate, wherein the first contact plug comprises a first contact part in the first interlayer insulating layer and a second contact part in the second interlayer insulating layer, wherein a density of the first interlayer insulating layer is smaller than a density of the second interlayer insulating layer, wherein the first contact part of the first contact plug has a first width, and wherein the second contact part of the first contact plug has a second width smaller than the first width.

According to one or more embodiments, an image sensor comprising: a substrate including a plurality of pixels; a first impurity region in the substrate in each of the pixels; a first interlayer insulating layer on the substrate; a second interlayer insulating layer on the first interlayer insulating layer; and a first contact plug passing through the second interlayer insulating layer and the first interlayer insulating layer and being in contact with the substrate, wherein the first contact plug comprises a first contact part in the first interlayer insulating layer and a second contact part in the second interlayer insulating layer, wherein a density of the first interlayer insulating layer is smaller than a density of the second interlayer insulating layer, wherein the first contact part of the first contact plug has a first width, and wherein the second contact part of the first contact plug has a second width smaller than the first width.

According to one or more embodiments, an image sensor comprising: a substrate comprising a plurality of pixels; a floating diffusion region in the substrate in each of the pixels; a first interlayer insulating layer covering the substrate; a second interlayer insulating layer on the first interlayer insulating layer; a first contact plug passing through the second interlayer insulating layer and the first interlayer insulating layer and being in contact with the substrate; a transfer gate pattern on the substrate next to the floating diffusion region in each of the pixels and covered with the second interlayer insulating layer, the transfer gate pattern comprising a gate insulating layer, a gate electrode, and a gate capping pattern; and a second contact plug passing through the second interlayer insulating layer and the gate capping pattern and being in contact with the gate electrode, and wherein a first distance between an upper portion of the first contact plug and an upper portion of the second contact plug is greater than a second distance between a lower portion of the first contact plug and a lower portion of the second contact plug.

According to one or more embodiments, a method of fabricating an image sensor, the method comprising: forming a pixel separator on a substrate to separate pixels; forming a first interlayer insulating layer on the substrate; forming a second interlayer insulating layer on the first interlayer insulating layer; etching the second interlayer insulating layer and the first interlayer insulating layer to form a first contact hole exposing the substrate; removing a part of the first interlayer insulating layer through the first contact hole to enlarge a lower portion of the first contact hole; and forming a first contact plug in the first contact hole.

### BRIEF DESCRIPTION OF DRAWINGS

Example embodiments will be more clearly understood from the following brief description taken in conjunction with the accompanying drawings. The accompanying drawings represent non-limiting, example embodiments as described herein.

FIG. 1 is a block diagram illustrating an image sensor according to one or more embodiments of the present disclosure.

FIG. 2 is a circuit diagram of an active pixel sensor array of an image sensor according to one or more embodiments of the present disclosure.

FIG. 3 is a plan view of one pixel of an image sensor according to one or more embodiments of the present disclosure.

FIG. 4 is a cross-sectional view of FIG. 3 taken along line A-A′ according to one or more embodiments of the present disclosure.

FIGS. 5A and 5B are enlarged views of portion ‘P1’ of FIG. 4 according to one or more embodiments of the present disclosure.

FIGS. 6A to 6H are cross-sectional views sequentially illustrating a process of fabricating an image sensor having the cross-section of FIG. 4.

FIG. 7 is a cross-sectional view of FIG. 3 taken along line A-A′ according to one or more embodiments of the present disclosure.

FIG. 8 is an enlarged view of portion ‘P2’ of FIG. 7 according to one or more embodiments of the present disclosure.

FIG. 9 is a cross-sectional view illustrating a method of fabricating an image sensor having the cross-section of FIG. 7.

FIG. 10 is a cross-sectional view of a semiconductor device according to one or more embodiments of the present disclosure.

FIG. 11 is a cross-sectional view of an image sensor according to one or more embodiments of the present disclosure.

FIG. 12 is a cross-sectional view of an image sensor according to one or more embodiments of the present disclosure.

### DETAILED DESCRIPTION

The embodiments described herein are example embodiments, and thus, the disclosure is not limited thereto and may be realized in various other forms. It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Spatially relative terms, such as “over,” “above,” “on,” “upper,” “below,” “under,” “beneath,” “lower,” “left,” “right,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Hereinafter, to explain the present disclosure in more detail, embodiments according to the present disclosure will be described in more detail with reference to the accompanying drawings. In this specification, terms indicating an order such as first and second are used to distinguish components performing the same/similar functions from each other, and the numbers may change depending on the order in which they are mentioned.

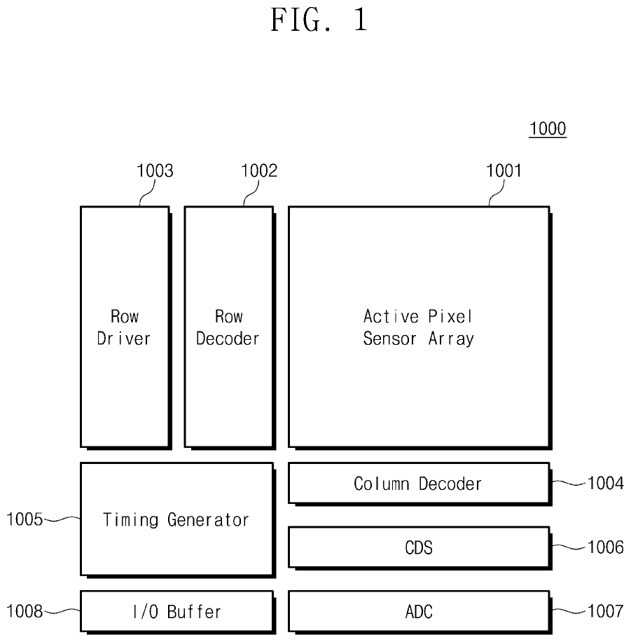

FIG. 1 is a block diagram illustrating an image sensor according to one or more embodiments of the present disclosure.

Referring to FIG. 1, an image sensor 1000 may generate a digital signal by receiving light from the outside. An electronic device including the image sensor 1000 may display an image on a display panel based on a digital signal. For example, the electronic device including the image sensor may be implemented as one of various types of electronic devices such as a smartphone, a tablet personal computer (PC), a laptop PC, a wearable device, or any other suitable device known to one of ordinary skill in the art.

According to one or more embodiments, the image sensor 1000 may include an active pixel sensor array 1001, a row decoder 1002, a row driver 1003, a column decoder 1004, a timing generator 1005, a correlated double sampler (CDS) 1006, an analog to digital converter (ADC) 1007, and an input/output (I/O) buffer 1008.

In one or more examples, the active pixel sensor array 1001 may include a plurality of unit pixels, which are two-dimensionally arranged, and may be configured to convert an optical signal to an electrical signal. The active pixel sensor array 1001 may be driven by a plurality of driving signals, such as a pixel selection signal, a reset signal, and a charge transfer signal, which are transmitted from the row driver 1003. In addition, the converted electrical signal may be provided to the correlated double sampler 1006.

The row driver 1003 may be configured to provide a plurality of driving signals for driving the unit pixels of the active pixel sensor array 1001, based on the result decoded by the row decoder 1002. In the case where the unit pixels are arranged in rows and columns, the driving signals may be provided to respective rows.

The timing generator 1005 may be configured to provide a timing signal and a control signal to the row decoder 1002 and the column decoder 1004.

The correlated double sampler 1006 may be configured to receive the electric signals generated by the active pixel sensor array 1001 and to perform a holding and sampling operation on the received electric signals. The correlated double sampler 1006 may perform a double sampling operation using a specific noise level and a signal level of the electric signal and then may output a difference level corresponding to a difference between the noise and signal levels.

The analog-to-digital converter 1007 may be configured to convert an analog signal, which contains information on the difference level outputted from the correlated double sampler 1006, to a digital signal and to output the converted digital signal.

The I/O buffer 1008 may be configured to latch the digital signals and then to sequentially output the latched digital signals to an image signal processing unit, based on the result decoded by the column decoder 1004.

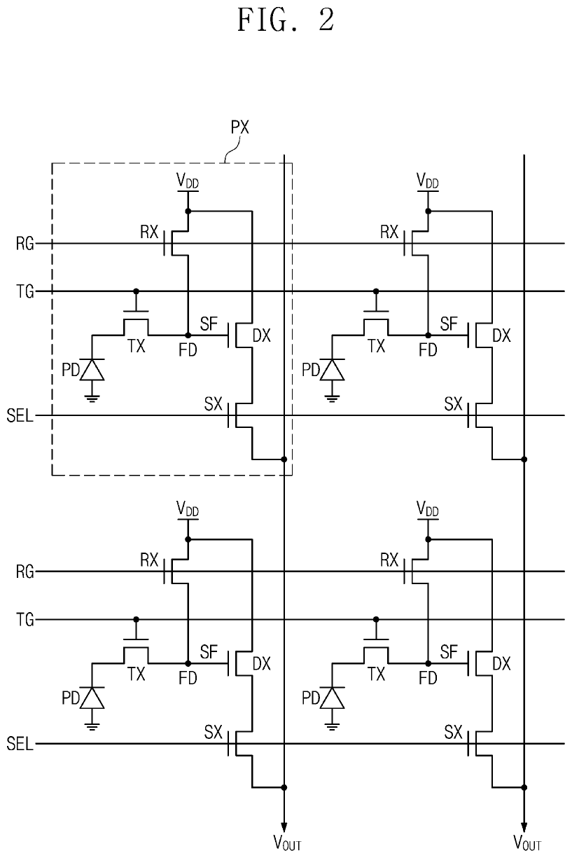

FIG. 2 is a circuit diagram of an active pixel sensor array of an image sensor according to one or more embodiments of the present disclosure.

Referring to FIGS. 1 and 2, the sensor array 1001 may include a plurality of unit pixels PX, which are arranged in a matrix shape. Each of the unit pixels PX may include a transfer transistor TX. Each of the unit pixels may further include logic transistors RX, SX, and DX. The logic transistors may include a reset transistor RX, a selection transistor SX, and a source follower transistor DX. The transfer transistor TX may include a transfer gate TG. Each of the unit pixels PX may further include a photoelectric converter PD and a floating diffusion region FD. The logic transistors RX, SX, and DX may be shared by a plurality of unit pixels PX.

In one or more examples, the photoelectric converter PD may be configured to generate photocharges having an amount that is proportional to an amount of externally incident light and to store the photocharges. The photoelectric converter PD may include a photo diode, a photo transistor, a photo gate, a pinned photo diode, or any combination thereof. The transfer transistor TX may be configured to transfer electric charges, which are generated in the photoelectric converter PD, to the floating diffusion region FD. The floating diffusion region FD may be configured to receive and cumulatively store the electric charges, which are generated in the photoelectric converter PD. The source follower transistor DX may be controlled, based on an amount of electric charges stored in the floating diffusion region FD.

In one or more examples, the reset transistor RX may be configured to periodically discharge or reset the electric charges stored in the floating diffusion region FD. The reset transistor RX may include drain and source electrodes, which are connected to the floating diffusion region FD and a power voltage VDD, respectively, and a reset gate electrode. When the reset transistor RX is turned on, the power voltage VDD connected to the source electrode of the reset transistor RX may be applied to the floating diffusion region FD. Thus, when the reset transistor RX is turned on, the electric charges stored in the floating diffusion region FD may be discharged (e.g., the floating diffusion region FD may be reset).

The source follower transistor DX including a source follower gate electrode SF may serve as a source follower buffer amplifier. The source follower transistor DX may be configured to amplify a variation in electric potential of the floating diffusion region FD and to output the amplified signal to an output line Vout.

The selection transistor SX including a selection gate electrode SEL may select one of the rows of the unit pixels PX, during reading operations. When the selection transistor SX is turned on, the power voltage VDD may be applied to a drain electrode of the source follower transistor DX.

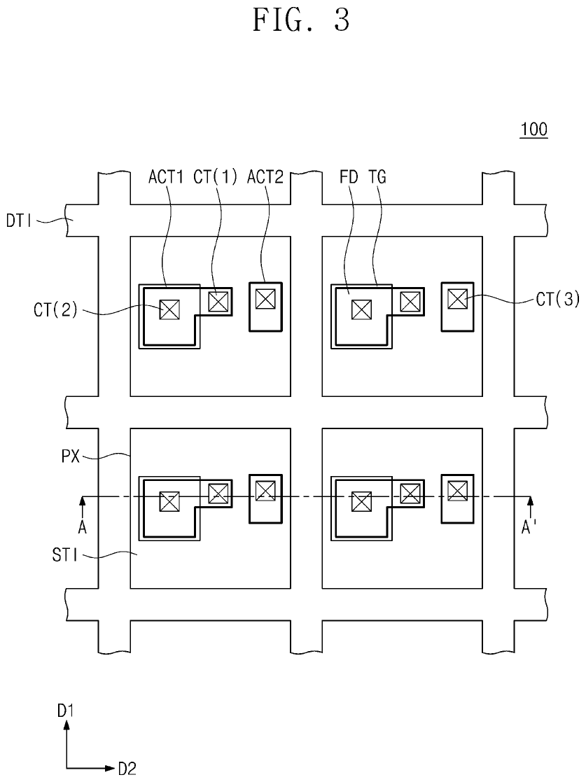

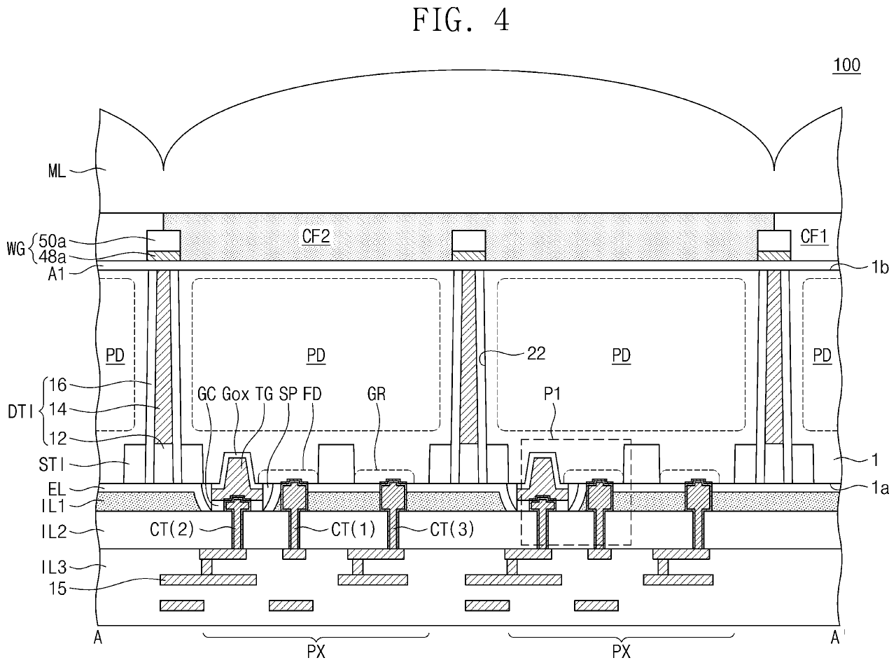

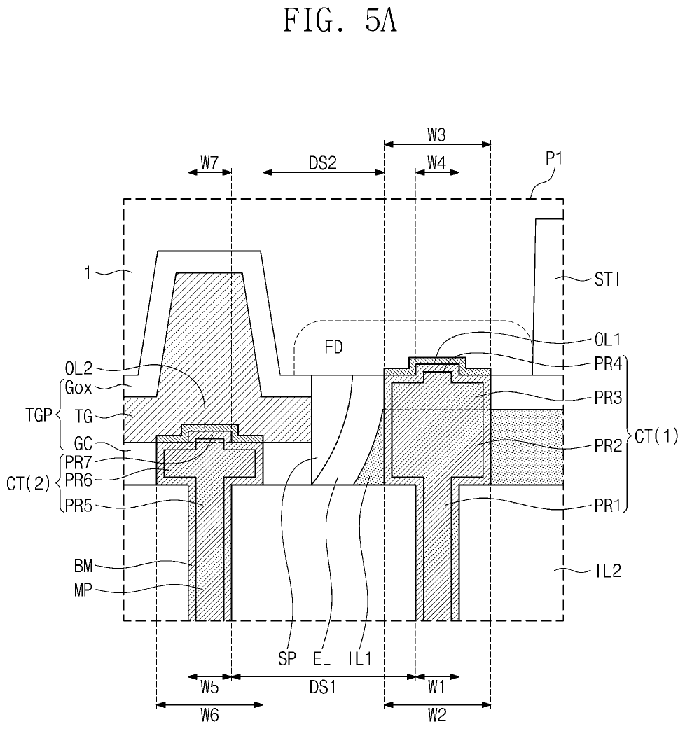

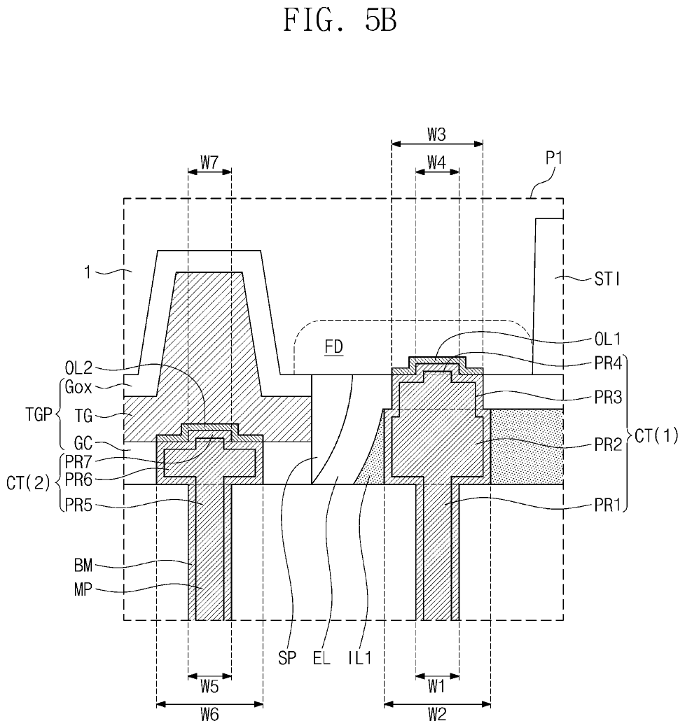

FIG. 3 is a plan view of one pixel of an image sensor according to one or more embodiments of the present disclosure. FIG. 4 is a cross-sectional view of FIG. 3 taken along line A-A′ according to one or more embodiments of the present disclosure. FIGS. 5A and 5B are enlarged views of portion ‘P1’ of FIG. 4 according to one or more embodiments of the present disclosure.

Referring to FIGS. 3 and 4, in the image sensor 100, according to one or more examples, a pixel separator DTI is disposed on a first substrate 1 to separate a plurality of pixels PX from each other. The first substrate 1 may be, for example, a silicon single crystal wafer, a silicon epitaxial layer, a silicon on insulator (SOI) substrate, or any other suitable material known to one of ordinary skill in the art. The first substrate 1 may be doped with impurities of a first conductivity type, for example. For example, the first conductivity type may be a P type. The first substrate 1 may include a front surface 1a and a rear surface 1b opposite to each other. In one or more examples, the front surface 1a may be referred to as a first surface 1a, and the rear surface 1b may also be referred to as a second surface 1b. The first substrate 1 may include a plurality of pixels PX. The pixel separator DTI may have a mesh shape or surface when viewed in a plan view.

In one or examples, the pixel separator DTI is disposed in a deep trench 22 formed from the front surface 1a to the rear surface 1b of the first substrate 1. The pixel separator DTI may include a filling insulating pattern 12, a separation insulating pattern 16, and a separation conductive pattern 14. The filling insulating pattern 12 may be interposed between the separation conductive pattern 14 and a first interlayer insulating layer IL1. The separation insulating pattern 16 may be interposed between the separation conductive pattern 14 and the first substrate 1 and between the filling insulation pattern 12 and the first substrate 1. For example, as illustrated in FIG. 4, the separation insulating pattern 16 is located on side surfaces of the separation conductive pattern 14 and the filling insulating pattern 12.

In one or more examples, the filling insulating pattern 12 and the separation insulating pattern 16 may be formed of an insulating material having a refractive index different from that of the first substrate 1. The filling insulating pattern 12 and the separation insulating pattern 16 may include, for example, silicon oxide. The separation conductive pattern 14 may be spaced apart from the first substrate 1. The separation conductive pattern 14 may include a polysilicon layer or a silicon germanium layer doped with impurities. The impurities doped into the polysilicon or silicon germanium layer may be, for example, one of boron, phosphorus and arsenic. In one or more examples, the separation conductive pattern 14 may include a metal layer.

A negative bias voltage may be applied to the separation conductive pattern 14. The separation conductive pattern 14 may serve as a common bias line. As a result, holes that may exist on a surface of the first substrate 1 in contact with the pixel separator DTI may be captured, thereby improving dark current characteristics.

In one or more examples, the pixel separator DTI may have varying width such that the pixel separator DTI has a narrower width from the front surface 1a to the rear surface 1b of the first substrate 1.

In one or more examples, in the pixels PX, photoelectric converters PD may be disposed in the first substrate 1. The photoelectric converters PD may be doped with impurities of a second conductivity type opposite to the first conductivity type. The second conductivity type may be, for example, an N type. The N-type impurities doped in the photoelectric converter PD may form a PN junction with P-type impurities doped in the first substrate 1, thereby providing a photodiode.

Device isolation parts STI adjacent to the front surface 1a may be disposed within the first substrate 1. The device isolation parts STI may be penetrated by the pixel separator DTI. The device isolation parts STI may define first and second active regions ACT1 and ACT2 adjacent to the front surface 1a in each unit pixel PX. The first active region ACT1 may be provided for the transfer transistor TX of FIG. 2. The second active region ACT2 may be provided for a ground region GR. In one or more examples, additional active regions for the logic transistors RX, SX, and DX (FIG. 2) may be provided on the front surface 1a of each unit pixel PX.

Referring to FIGS. 4 and 5A, a transfer gate TG may be disposed on the front surface 1a of the first substrate 1 in each unit pixel PX. A portion of the transfer gate TG may extend into the first substrate 1 in a direction towards surface 1b. The transfer gate TG may be—of a vertical type. In one or more examples, the transfer gate TG may be of a planar type that does not extend into the first substrate 1 and has a flat shape. The transfer gate TG may have a single layer structure or a multilayer structure of at least one of impurity-doped polysilicon, metal nitride, and/or metal. The transfer gate TG may include multi-layered polysilicon layers having different impurity concentrations.

A gate insulating layer Gox may be interposed between the transfer gate TG and the first substrate 1. For example, as illustrated in FIG. 4, the gate insulating layer Gox is disposed on a top surface of the transfer gate TG. A floating diffusion region FD may be disposed in the first substrate 1 adjacent to the transfer gate TG. In one or more examples, the floating diffusion region FD may be doped with impurities of the second conductivity type. A gate capping pattern GC may be disposed below the transfer gate TG. The gate insulating layer Gox, the transfer gate TG, and the gate capping pattern GC may constitute a transfer gate pattern TGP. A sidewall of the transfer gate TG may be covered with a gate spacer SP. Each of the gate capping pattern GC and the gate spacer SP may have a single layer structure or a multilayer structure of at least one of silicon oxide, silicon nitride, and silicon oxynitride.

The ground region GR may be disposed on the first substrate 1 in each unit pixel PX. In one or more examples, the ground region GR may be doped with impurities of the first conductivity type. A concentration of first-conductive-type impurities doped in the ground region GR may be greater than a concentration of first-conductive-type impurities doped in the first substrate 1.

According to one or more embodiments, the image sensor 100 may be a rear light receiving image sensor. Light may be incident into the first substrate 1 through the rear surface 1b of the first substrate 1. Electron-hole pairs may be generated in the PN junction by incident light. Electrons, thus generated, may move to the photoelectric converter PD. When a voltage is applied to the transfer gate TG, the electrons may move to the floating diffusion region FD.

In one or more examples, a reset transistor RX, a selection transistor SX, and a source follower transistor DX may be disposed on the front surface 1a of the pixels PX.

The front surface 1a may be covered with an etch stop layer EL. In one or more examples, the etch stop layer EL has a single layer or multilayer structure of at least one of silicon oxide, silicon nitride, and silicon oxynitride. A lowermost surface of the etch stop layer EL may be coplanar with a lower surface of the gate capping pattern GC. The etch stop layer EL may be covered by a first interlayer insulating layer IL1. A lower surface of the first interlayer insulating layer IL1 may be coplanar with a lowermost surface of the etch stop layer EL and a lower surface of the gate capping pattern GC. The lower surface of the first interlayer insulating layer IL1, the lowermost surface of the etch stop layer EL, and the lower surface of the gate capping pattern GC may be covered with a second interlayer insulating layer IL2. A density of the first interlayer insulating layer IL1 may be smaller than that of the second interlayer insulating layer IL2. The density of the insulating layers may be determined by a porosity of a respective insulating layer. For example, porosity of the first interlayer insulating layer IL1 may be greater than that of the second interlayer insulating layer IL2. A permittivity (or dielectric constant) of the first interlayer insulating layer IL1 may be smaller than a permittivity (or dielectric constant) of the second interlayer insulating layer IL2.

The first interlayer insulating layer IL1 may be formed of a high aspect ratio process (HARP) oxide, flowable chemical vapor deposition (FCVD) oxide, Tonen SilaZene (TOSZ), plasma enhanced oxide (PEOX), borophosphorosilicate glass (BPSG), or any other suitable material known to one of ordinary skill in the art. The second interlayer insulating layer IL2 may be formed of tetraethyl orthosilicate (TEOS) or high-density-plasma (HDP) oxide, or any other suitable material known to one of ordinary skill in the art.

According to one or more embodiments, contact plugs CT(1) to CT(3) penetrate the second interlayer insulating layer IL2. As illustrated in FIG. 5A, the first contact plug CT(1) penetrates the second interlayer insulating layer IL2, the first interlayer insulating layer IL1, and the etch stop layer EL to be in contact with the floating diffusion region FD of the first substrate 1. The first contact plug CT(1) may include a first part PR1 in the second interlayer insulating layer IL2, a second part PR2 in the first interlayer insulating layer IL1, and a third part PR3 in the etch stop layer EL. A fourth part PR4 of the first contact plug CT(1) may be inserted into the first substrate 1. The first to fourth parts PR1 to PR4 may be integrally connected to each other. In one or more examples, the first to fourth parts PR1 to PR4 may be made of the same material. In one or more examples, at least one of the first to fourth parts PR1 to PR4 may be made with a material different than a material for the other parts.

The first part PR1 may have a first width W1. The second part PR2 may have a second width W2. The third part PR3 may have a third width W3. The fourth part PR4 may have a fourth width W4. Each of the second and third widths W2 and W3 may be greater than the first width W1. The fourth width W4 may be equal to or smaller than the first width W1. The third width W3 may be the same as or different from the second width W2. The third width W3 may be equal to the second width W2 as shown in FIG. 5A or smaller than the second width W2 as shown in FIG. 5B.

The second contact plug CT(2) may include a fifth part PR5 in the second interlayer insulating layer IL2 and a sixth part PR6 in the gate capping pattern GC. A seventh part PR7 of the second contact plug CT(2) may be inserted into the transfer gate TG. The fifth to seventh parts PR5 to PR7 may be integrally connected to each other. In one or more examples, the fifth to seventh parts PR5 to PR7 may be made of the same material. In one or more examples, at least one of the fifth to seventh parts PR5 to PR7 may be made with a material different than a material for the other parts.

The fifth part PR5 may have a fifth width W5. The sixth part PR6 may have a sixth width W6. The seventh part PR7 may have a seventh width W7. The sixth width W6 may be greater than the fifth width W5. The seventh width W7 may be equal to or smaller than the fifth width W5.

As illustrated in FIG. 5A, in one or more examples, a first ohmic layer OL1 may be disposed between the first contact plug CT(1) and the first substrate 1. A second ohmic layer OL2 may be disposed between the second contact plug CT(2) and the transfer gate TG. Each of the first and second ohmic layers OL1 and OL2 may include a metal silicide layer. The first ohmic layer OL1 may have the third width W3 and the second ohmic layer OL2 may have the sixth width W6. Accordingly, a contact resistance between the first contact plug CT(1) and the first substrate 1 and a contact resistance between the second contact plug CT(2) and the transfer gate TG may be reduced.

A permittivity (or dielectric constant) of the first interlayer insulating layer IL1 may be smaller than a permittivity (or dielectric constant) of the second interlayer insulating layer IL2, a parasitic capacitance between the second part PR2 of the first contact plug CT(1) and the sixth part PR6 of the second contact plug CT(2) may be advantageously reduced.

Each of the first contact plug CT(1) and the second contact plug CT(2) may include a metal pattern MP and a diffusion barrier pattern BM conformally forming a sidewall thereof. The metal pattern MP may include one of tungsten, aluminum, copper, nickel, iridium, rhodium, cobalt, molybdenum, ruthenium, or any other suitable material known to one of ordinary skill in the art. The diffusion barrier pattern BM may have a single layer or multilayer structure of at least one of titanium, titanium nitride, tantalum, and tantalum nitride.

A first distance DS1 between the first part PR1 of the first contact plug CT(1) and the fifth part PR5 of the second contact plug CT(2) is greater than a second distance DS2 between the second part PR2 of the first contact plug CT(1) and the sixth part PR6 of the second contact plug CT(2). As a result of these features, a parasitic capacitance between the first part PR1 of the first contact plug CT(1) and the fifth part PR5 of the second contact plug CT(2) may be advantageously reduced.

As illustrated in FIG. 4, in one or more examples, the third contact plug CT(3) penetrates the second interlayer insulating layer IL2, the first interlayer insulating layer IL1, and the etch stop layer EL to be in contact with the ground region GR of the first substrate 1. The third contact plug CT(3) may have the same structure as the first contact plug CT(1). In one or more examples, the third contact plug CT(3) may have the same shape as the first contact plug CT(1) with a different size than the first contact plug CT (1).

In the present disclosure, based on the structure of the first to third contact plugs CT(1) to CT(3) described above, and the physical characteristics of the first and second interlayer insulating layers IL1 and IL2 as described above, the parasitic capacitance between the first to third contact plugs CT(1) to CT(3) may be advantageously reduced, thereby preventing/minimizing signal interference, and the first to third contact plugs CT(1) to CT(3) may advantageously reduce the contact resistance between the first substrate 1 and the transfer gate TG, thereby improving signal transmission speed and reducing driving voltage. Accordingly, it is possible to provide an image sensor with improved characteristics.

In one or more examples, a third interlayer insulating layer IL3 may be disposed below the second interlayer insulating layer IL2. The third interlayer insulating layer IL3 may have a single layer or multilayer structure of at least one of silicon oxide, silicon nitride, silicon oxynitride, SiCN, a porous insulating layer, and any other suitable material known to one of ordinary skill in the art. Multi-layered first wirings 15 may be disposed in the third interlayer insulating layer IL3 and may be connected to first to third contact plugs CT(1) to CT(3).

In one or more examples, the rear surface 1b of the first substrate 1 may be covered with a fixed charge layer A1. The fixed charge layer A1 may be in contact with the rear surface 1b. The fixed charge layer A1 may have a negative fixed charge. The fixed charge layer A1 may be formed of a metal oxide and a metal fluoride including at least one metal selected from the group consisting of hafnium (Hf), zirconium (Zr), aluminum (Al), tantalum (Ta), titanium (Ti), yttrium, lanthanoids, and any other suitable material known to one of ordinary skill in the art. For example, the fixed charge layer A1 may be a hafnium oxide layer or an aluminum oxide layer. In one or more examples, hole accumulation may occur around the fixed charge layer A1. As a result, generation of dark current and white spots may be effectively reduced.

A grid pattern WG may be disposed on the fixed charge layer A1. The grid pattern WG may include a light blocking pattern 48a and a low refractive index pattern 50a sequentially stacked. The grid pattern WG may overlap the pixel separator DTI. The light blocking pattern 48a may include, for example, at least one of titanium, titanium nitride, and tungsten. The low refractive index pattern 50a may include a material having a refractive index smaller than that of the color filters CF1 and CF2. In one or more examples, the low refractive pattern 50a has a refractive index of 1.3 or less. Sidewalls of the light blocking pattern 48a are aligned with sidewalls of the low refractive index pattern 50a.

Color filters CF1 and CF2 may be disposed between the grid patterns WG. In one or more examples, the color filters may be embedded within a color filter, or embedded within two adjacent color filters. One of the color filters CF1 and CF2 may simultaneously cover four adjacent unit pixels PX. The color filters CF1 and CF2 may be arranged in a Bayer pattern. In one or more examples, the color filters CF1 and CF2 may be arranged in a 2×2 tetra pattern, a 3×3 nona pattern, or a 4×4 hexadeca pattern.

Micro lenses ML may be respectively disposed on the color filters CF1 and CF2. One micro lens ML may simultaneously cover four adjacent unit pixels PX.

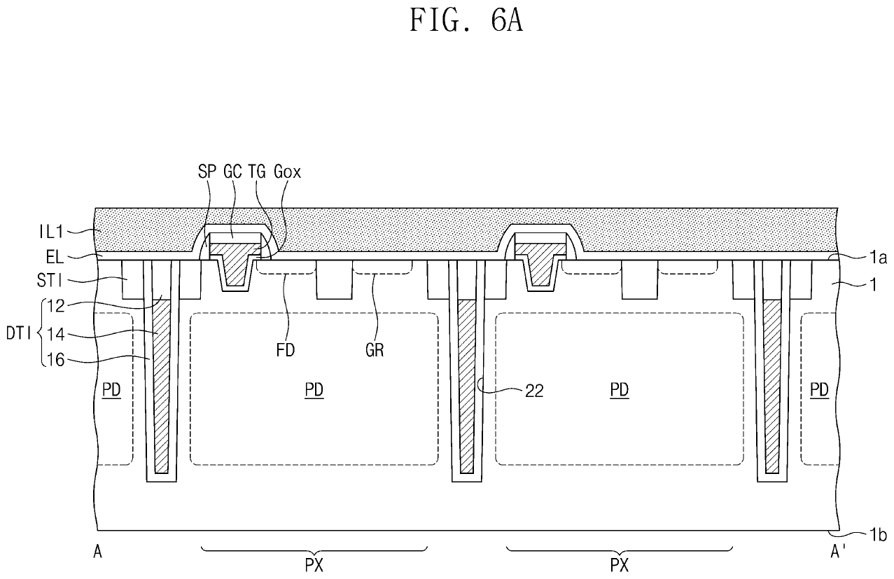

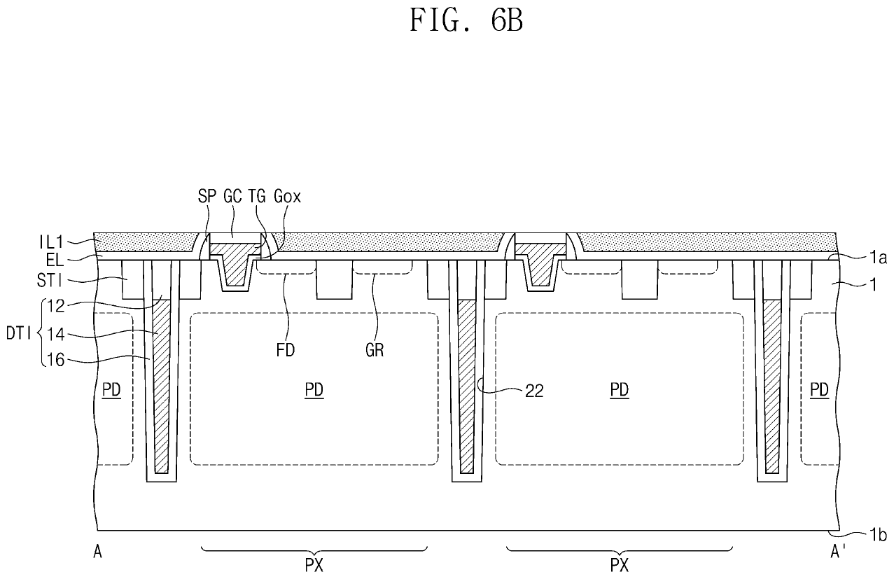

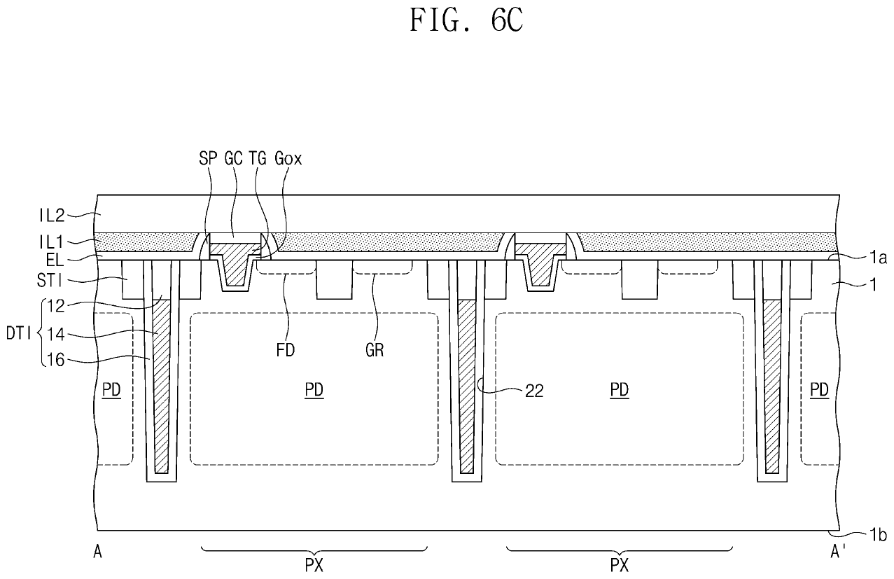

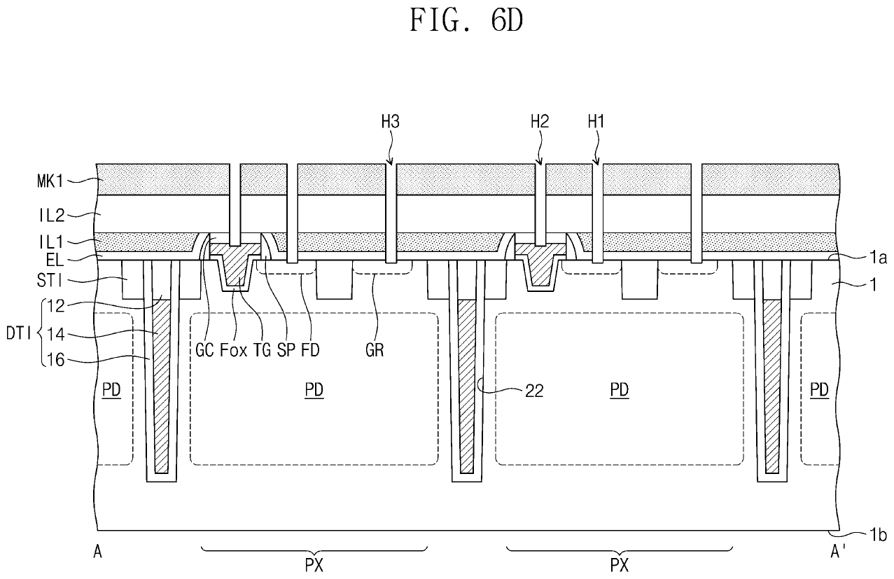

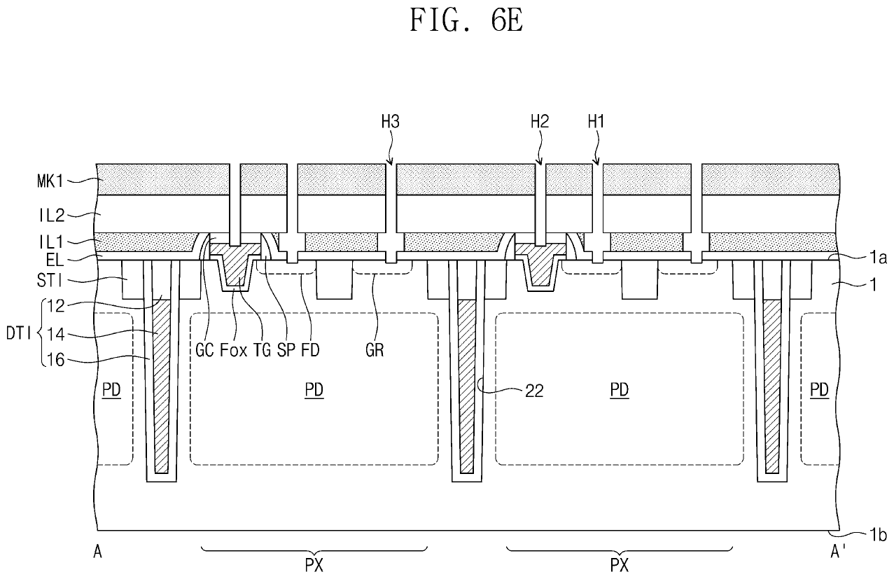

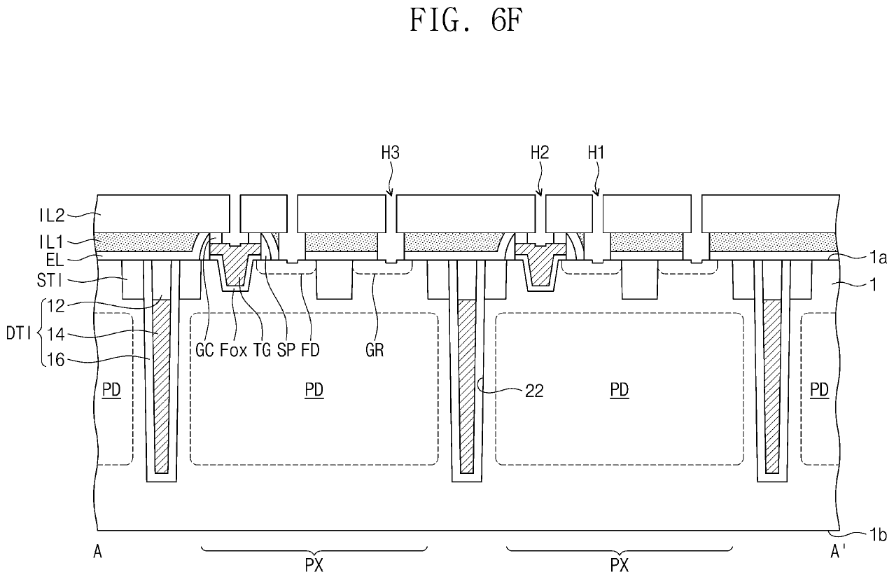

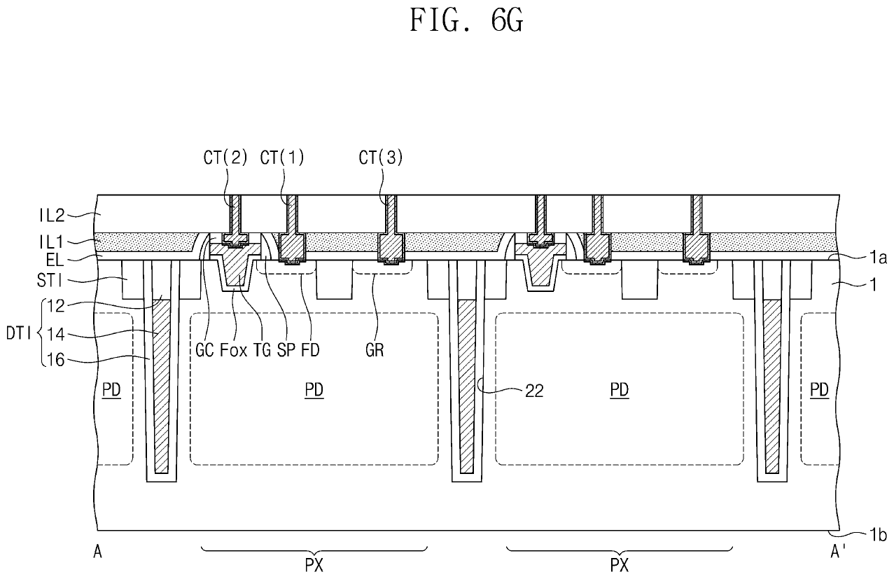

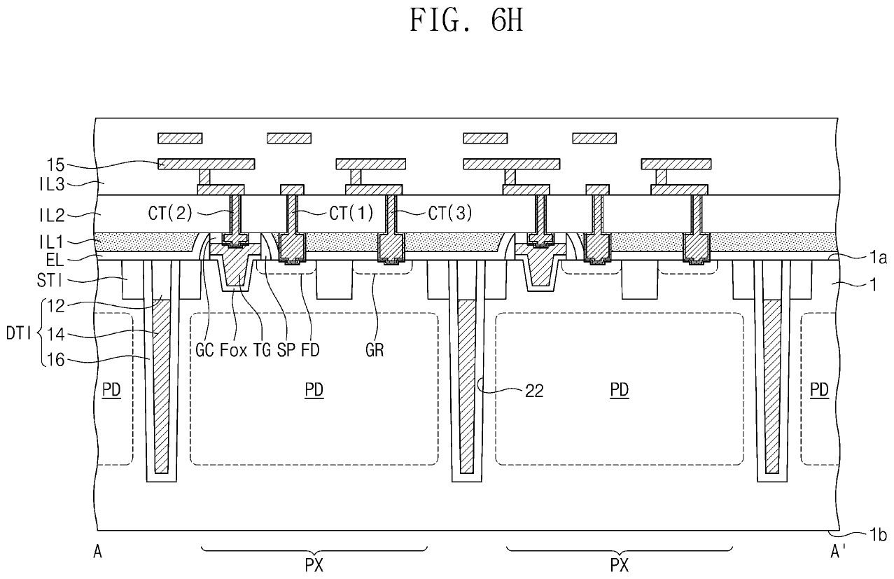

FIGS. 6A to 6H are cross-sectional views sequentially illustrating a process of fabricating an image sensor having the cross-section of FIG. 4. The orientation of the devices in FIGS. 6A-6H is reversed with respect to FIG. 4.

Referring to FIG. 6A, a photoelectric converter PD, a first device isolation part STI, a pixel separator DTI, a gate insulating layer Gox, a transfer gate TG, a gate capping pattern GC, a gate spacer SP, a floating diffusion region FD, and a ground region GR are formed in a first substrate 1 in a general manner. An etch stop layer EL is conformally formed on the first surface 1a of the first substrate 1. A first interlayer insulating layer IL1 is formed on the etch stop layer EL. The first interlayer insulating layer IL1 may be formed of high aspect ratio process (HARP) oxide, flowable chemical vapor deposition (FCVD) oxide, tonen silaZene (TOSZ), plasma enhanced oxide (PEOX), borophosphorosilicate glass (BPSG), or any other suitable material known to one of ordinary skill in the art.

Referring to FIG. 6B, a planarization process is performed on the first interlayer insulating layer IL1. For example, an etch-back or chemical mechanical polishing (CMP) process is performed on the first interlayer insulating layer IL1 to remove a portion of the etch stop layer EL and the first interlayer insulating layer IL1 on the gate capping pattern GC, to expose an upper surface of the gate capping pattern GC.

Referring to FIG. 6C, a second interlayer insulating layer IL2 is formed on the first interlayer insulating layer IL1. The second interlayer insulating layer IL2 may be formed of an insulating material having a different etch rate from that of the first interlayer insulating layer IL1. For example, the second interlayer insulating layer IL2 may be formed of an insulating material having an etch rate smaller than that of the first interlayer insulating layer IL1. In one or more examples, a density of the second interlayer insulating layer IL2 is greater than that of the first interlayer insulating layer IL1. A porosity of the second interlayer insulating layer IL2 may be smaller than that of the first interlayer insulating layer IL1. A permittivity (or dielectric constant) of the second interlayer insulating layer IL2 is greater than a permittivity (or dielectric constant) of the first interlayer insulating layer IL1. The second interlayer insulating layer IL2 may be formed of tetraethyl orthosilicate (TEOS) or high-density-plasma (HDP) oxide.

Referring to FIG. 6D, in one or more examples, a first mask pattern MK1 is formed on the second interlayer insulating layer IL2. The first mask pattern MK1 may be a photoresist pattern. In one or more examples, the first mask pattern MK1 may have a structure of at least one single layer or multilayer selected from among silicon oxide, silicon oxynitride, polysilicon, silicon germanium, spin on hardmask (SOH), amorphous carbon layer (ACL), and any other suitable material known to one of ordinary skill in the art. The first mask pattern MK1 may have a plurality of holes defining first to third contact holes H1 to H3.

In one or more examples, the second interlayer insulating layer IL2, the first interlayer insulating layer IL1, the etch stop layer EL, and the gate capping pattern GC are etched using the first mask pattern MK1 as an etch mask, to form the first to third contact holes H1 to H3. The first and third contact holes H1 and H3 in the second interlayer insulating layer IL2 may each have a first width W1 as shown in FIG. 5A. The second contact hole H2 in the second interlayer insulating layer IL2 may be formed to have a fifth width W5 as shown in FIG. 5A. The first contact hole H1 may expose the floating diffusion region FD (e.g., providing a path to the floating diffusion region FD). The second contact hole H2 may expose the transfer gate TG (e.g., providing a path to the transfer gate TG). The third contact hole H3 may expose the ground region GR (e.g., providing a path to the ground region GR). When the first to third contact holes H1 to H3 are formed, a portion of the first substrate 1 and a portion of the transfer gate TG may be etched. In the first substrate 1, the first and third contact holes H1 and H3 in the first substrate 1 may each have a fourth width W4 as shown in FIG. 5A. The fourth width W4 may be equal to or smaller than the first width W1. The second contact hole H2 in the transfer gate TG may be formed to have a seventh width W7 as shown in FIG. 5A. The seventh width W7 may be equal to or smaller than the fifth width W5.

Referring to FIG. 6E, in one or more examples, a first isotropic etching process using a first etchant (e.g., hydrofluoric acid) is performed to partially remove the first interlayer insulating layer IL1 through the first and third contact holes H1 and H3. Accordingly, lower portions of the first and third contact holes H1 and H3 may be wider than the first width W1. In the first interlayer insulating layer IL1, the first and third contact holes H1 and H3 may each have a second width W2 as shown in FIG. 5A. In the first isotropic etching process, a portion of the second interlayer insulating layer IL2 may be removed to enlarge the first width W1 and the fifth width W5. However, since an etching rate of the second interlayer insulating layer IL2 is smaller than that of the first interlayer insulating layer IL1, and an amount of the first interlayer insulating layer IL1 is removed more than interlayer insulating layer IL2, the second width W2 is greater than the first width W1.

Referring to FIG. 6F, the first mask pattern MK1 is removed. A second isotropic etching process is performed using a second etchant (e.g., phosphoric acid) to partially remove the etch stop layer EL and the gate capping pattern GC through the first to third contact holes H1 to H3. As a result, the area of the first substrate 1 exposed by the first and third contact holes H1 and H3 may be increased and the area of the transfer gate TG exposed by the second contact hole H2 may be increased. The first and third contact holes H1 and H3 in the etch stop layer EL may each have a third width W3 as shown in FIG. 5A. The second contact hole H2 in the gate capping pattern GC may be formed to have a sixth width W6 as shown in FIG. 5A. The third width W3 may be greater than the first width W1. The sixth width W6 may be greater than the fifth width W5.

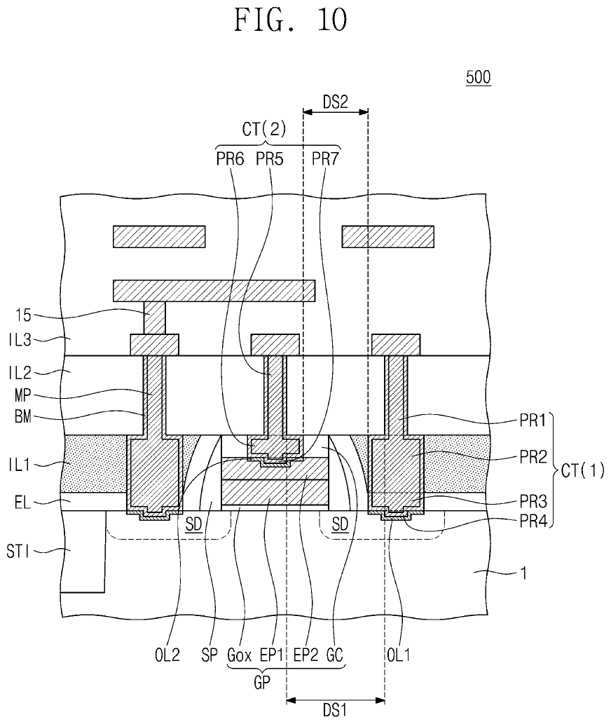

Referring to FIGS. 5A and 6G, a diffusion barrier layer is conformally stacked on the second interlayer insulating layer IL2 and a contact metal layer is stacked thereon to fill the first to third contact holes H1 to H3. Before forming the diffusion barrier layer, an ohmic metal layer may be conformally stacked on the second interlayer insulating layer IL2 and a heat treatment (e.g., annealing) process may be performed, first and second ohmic layers OL1 and OL2 may be formed on bottom surfaces of the first to third contact holes H1 to H3 of FIG. 6F and the remaining ohmic metal layer may be removed. In one or more examples, a portion of the diffusion barrier layer may react with a portion of the first substrate 1 and the transfer gate TG on bottom surfaces of the first to third contact holes H1 to H3 when forming the diffusion barrier layer, and thus, the first and second ohmic layers OL1 and OL2 may also be formed. A chemical mechanical polishing (CMP) process is performed for the contact metal layer and the diffusion barrier layer, the contact metal layer and the diffusion barrier layer on the second interlayer insulating layer IL2 are removed, and first to third contact plugs CT(1) to CT(3) are formed in the first to third contact holes H1 to H3. Accordingly, each of the first to third contact plugs CT(1) to CT(3) may be formed to include a diffusion barrier pattern BM (FIG. 10), which is a portion of the diffusion barrier layer, and a metal pattern MP, which is a portion of the contact metal layer, as illustrated in FIG. 5A.

Referring to FIG. 6H, in one or more examples, a third interlayer insulating layer IL3 and first wirings 15 are formed on the second interlayer insulating layer IL2 by performing a general process. Referring to FIG. 4, a back-grinding process is performed on the second surface 1b of the first substrate 1 to partially remove the first substrate 1 adjacent to the second surface 1b, thereby forming pixels. A separation conductive pattern 14 of the pixel separator DTI may be exposed. Subsequently, a fixed charge layer A1, a grid pattern WG, color filters CF1 and CF2, and micro lenses ML are formed on the second surface 1b in a general manner.

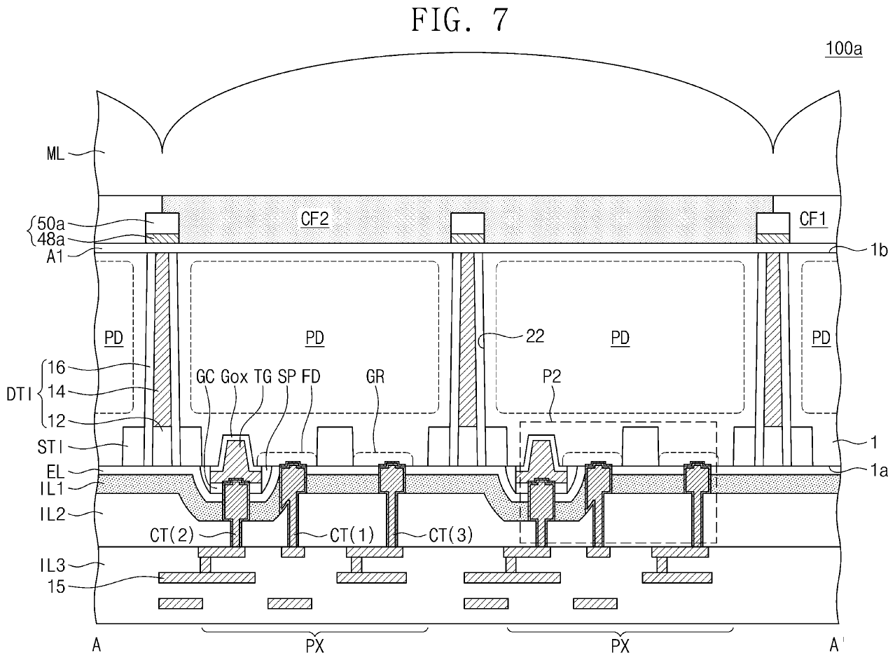

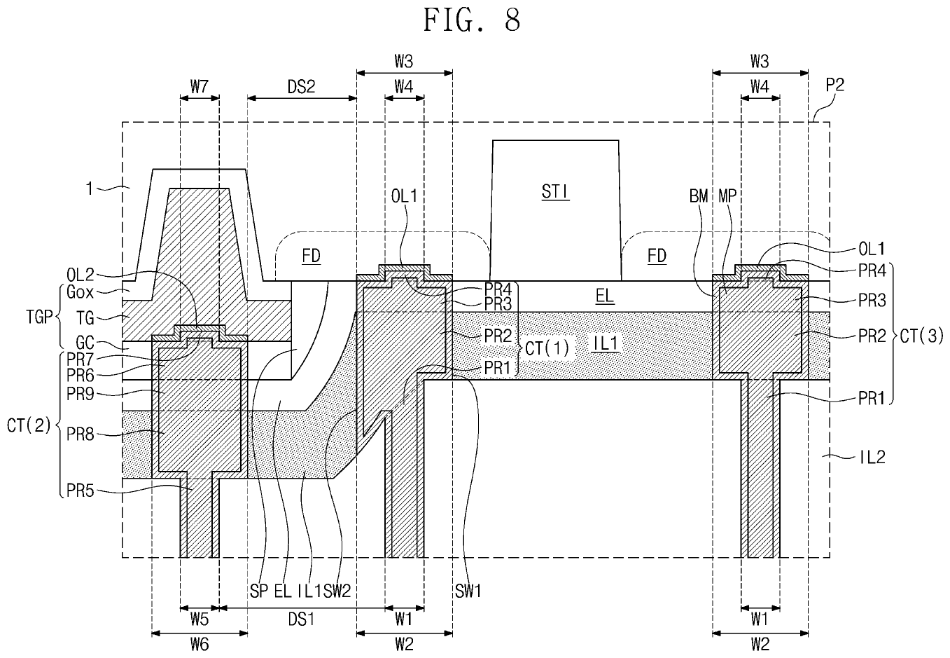

FIG. 7 is a cross-sectional view of FIG. 3 taken along line A-A′ according to one or more embodiments of the present disclosure. FIG. 8 is an enlarged view of portion ‘P2’ of FIG. 7 according to one or more embodiments of the present disclosure.

Referring to FIGS. 7 and 8, in an image sensor 100a according to one or more embodiments, the etch stop layer EL and the first interlayer insulating layer IL1 are formed to a constant thickness regardless of positions of these layers, and cover a lower surface of the gate capping pattern GC. Each of the second and third parts PR2 and PR3 of the first contact plug CT(1) may have a first sidewall SW1 and a second sidewall SW2 opposite to each other. The first sidewall SW1 may have a first length LT1. The second sidewall SW2 may have a second length LT2. The second length LT2 may be the same as or different from the first length LT1. For example, the second length LT2 may be longer than the first length LT1. In one or more examples, a shape or size of the first contact plug CT(1) may be different from that of the second contact plug CT(2).

The second contact plug CT(2) may be connected to the transfer gate TG by passing through the second interlayer insulating layer IL2, the first interlayer insulating layer IL1, the etch stop layer EL, and the gate capping pattern GC. The second contact plug CT(2) may further include an eighth part PR8 in the first interlayer insulating layer IL1 and a ninth part PR9 in the etch stop layer EL. The eighth part PR8 and the ninth part PR9 may each have the same or different widths. For example, the eighth part PR8 and the ninth part PR9 may each have a sixth width W6. As understood by one of ordinary skill in the art, other structures may be the same/similar to those described with reference to FIGS. 3 to 5B.

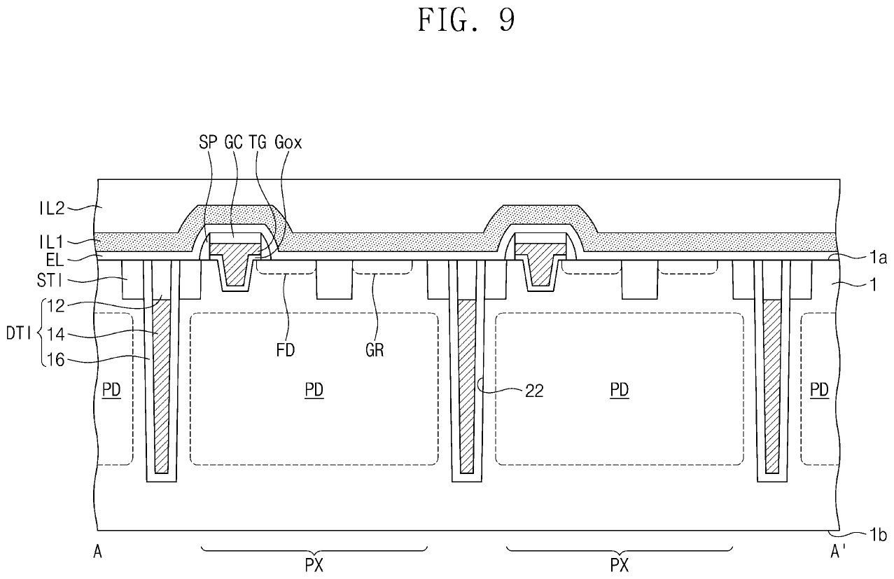

FIG. 9 is a cross-sectional view illustrating a method of fabricating an image sensor having the cross-section of FIG. 7.

Referring to FIG. 9, in one or more examples, the etch stop layer EL and the first interlayer insulating layer IL1 are sequentially conformally formed on the first surface 1a of the first substrate 1 on which the transfer gate TG, the gate capping pattern GC, and the gate spacer SP are formed. In addition, the second interlayer insulating layer IL2 is formed on the first interlayer insulating layer IL1 and a planarization process is performed on the second interlayer insulating layer IL2 to form a flat upper surface of the second interlayer insulating layer IL2. Subsequently, as shown in FIG. 6D, the image sensor of FIG. 7 may be manufactured by forming the first mask pattern MK1 on the second interlayer insulating layer IL2 and performing processes subsequent to the process of FIG. 6D.

FIG. 10 is a cross-sectional view of a semiconductor device according to one or more embodiments of the present disclosure.

Referring to FIG. 10, in a semiconductor device 500 according to one or more embodiments, a device isolation part STI is disposed on a first substrate 1 to define an active region. A gate pattern GP is disposed on the first substrate 1. The gate pattern GP may include a gate insulating layer Gox, a first gate electrode EP1, a second gate electrode EP2, and a gate capping pattern GC that are sequentially stacked. The first gate electrode EP1 may be formed of, for example, polysilicon doped with a first impurity at a first concentration. The second gate electrode EP2 may include metal. In one or more examples, the second gate electrode EP2 may be formed of polysilicon doped with a first impurity at a second concentration. The second concentration may be different from the first concentration. For example, the second concentration may be greater than the first concentration.

Both sidewalls of the gate pattern GP are covered with a gate spacer SP. Source/drain regions SD are disposed in the first substrate 1 adjacent to both sidewalls of the gate pattern GP. The gate pattern GP is covered with an etch stop layer EL. A first interlayer insulating layer IL1 may be disposed on the etch stop layer EL. Upper surfaces of the first interlayer insulating layer IL1 and the etch stop layer EL may be coplanar with an upper surface of the gate pattern GP.

The etch stop layer EL has a single layer or multilayer structure of at least one of silicon oxide, silicon nitride, silicon oxynitride, and any other suitable material known to one of ordinary skill in the art. The first interlayer insulating layer IL1 may be formed of high aspect ratio process (HARP) oxide, flowable chemical vapor deposition (FCVD) oxide, tonen silaZene (TOSZ), plasma enhanced oxide (PEOX), and borophosphorosilicate glass (BPSG), or any other suitable material known to one of ordinary skill in the art.

A second interlayer insulating layer IL2 is disposed on the first interlayer insulating layer IL1 and the gate pattern GP. In one or more examples, a density of the first interlayer insulating layer IL1 is smaller than that of the second interlayer insulating layer IL2. For example, a porosity of the first interlayer insulating layer IL1 may be greater than that of the second interlayer insulating layer IL2. A permittivity (or dielectric constant) of the first interlayer insulating layer IL1 is smaller than a permittivity (or dielectric constant) of the second interlayer insulating layer IL2. The second interlayer insulating layer IL2 may be formed of tetraethyl orthosilicate (TEOS) or high-density-plasma (HDP) oxide.

A first contact plug CT(1) may pass through the second interlayer insulating layer IL2, the first interlayer insulating layer IL1, and the etch stop layer EL to be in contact with the source/drain region SD. The first contact plug CT(1) may have the same shape as the first contact plug CT(1) described with reference to FIGS. 5A and 5B, respectively. A second contact plug CT(2) may penetrate the second interlayer insulating layer IL2 and the gate capping pattern GC to be in contact with the second gate electrode EP2. A first ohmic layer OL1 may be disposed between the first contact plug CT(1) and the first substrate 1. A second ohmic layer OL2 may be disposed between the second contact plug CT(2) and the second gate electrode EP2. The second contact plug CT(2) may have the same shape as the second contact plug CT(2) described with reference to FIGS. 5A and 5B.

As illustrated in FIGS. 5A and 5B, the first ohmic layer OL1 may have a third width W3 and the second ohmic layer OL2 may have a sixth width W6. Accordingly, a contact resistance between the first contact plug CT(1) and the first substrate 1 and a contact resistance between the second contact plug CT(2) and the second gate electrode EP2 may be advantageously reduced.

As illustrated in FIG. 10, a first distance DS1 between the first part PR1 of the first contact plug CT(1) and the fifth part PR5 of the second contact plug CT(2) is greater than a second distance DS2 between the second part PR2 of the first contact plug CT(1) and the sixth part PR6 of the second contact plug CT(2). As a result, a parasitic capacitance between the first part PR1 of the first contact plug CT(1) and the fifth part PR5 of the second contact plug CT(2) may be advantageously reduced.

A third interlayer insulating layer IL3 and multi-layered first wirings 15 may be disposed on the second interlayer insulating layer IL2. The semiconductor device according to the present disclosure has the described-above structure to prevent/minimize signal interference, improve signal transmission speed, and reduce driving voltage. Accordingly, the semiconductor device with improved characteristics may be provided.

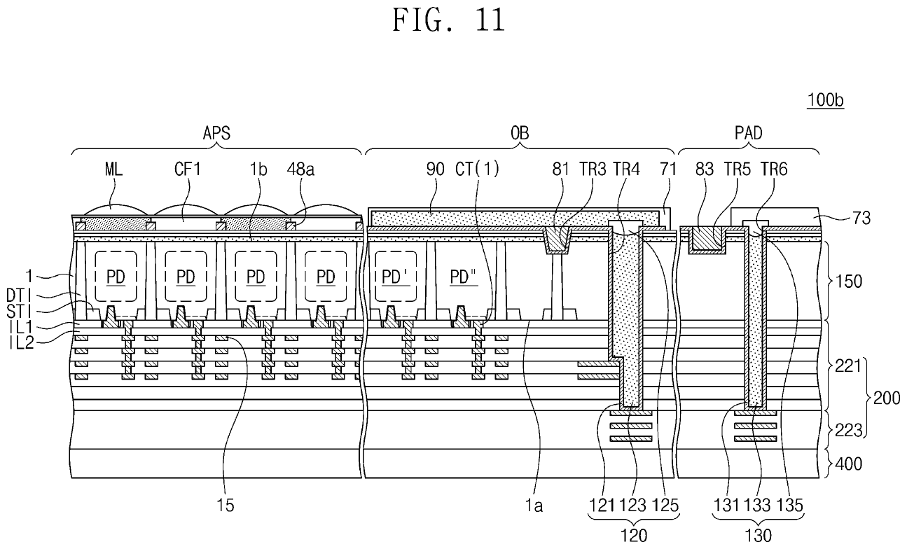

FIG. 11 is a cross-sectional view of an image sensor according to one or more embodiments of the present disclosure.

Referring to FIG. 11, an image sensor 100b according to the present example may include a first substrate I having a pixel array area APS, an optical black area OB, and a pad area PAD, a wiring layer 200 on a front surface 1a of the first substrate 1, and a second substrate 400 on the wiring layer 200. The wiring layer 200 may include an upper wiring layer 221 and a lower wiring layer 223. The pixel array area APS may include a plurality of pixels PX. The pixels PX disposed in the pixel array area APS may be substantially the same as those previously described with reference to FIGS. 3 to 5B, 7 and 8. The upper wiring layer 221 may include first and second interlayer insulating layers IL1 and IL2 and first to third contact plugs CT(1) to CT(3) described with reference to FIGS. 3 to 5B, 7, and 8.

In one or more examples, a light blocking pattern 48a, a first connection structure 120, a first conductive pad 81, and a bulk color filter 90 may be provided on the first substrate 1 in the optical black area OB. The first connection structure 120 may include a first connection line 121, an insulating pattern 123, and a first capping pattern 125.

In one or more examples, a portion of the first connection line 121 may be provided on a rear surface 1b of the first substrate 1. The first light blocking pattern 48a may cover the rear surface 1b and conformally cover inner walls of a third trench TR3 and a fourth trench TR4. The first connection line 121 may pass through a photoelectric conversion layer 150 and the upper wiring layer 221 to connect the photoelectric conversion layer 150 and the wiring layer 200. In one or more examples, the first connection line 121 may be in contact with wirings in the upper wiring layer 221 and the lower wiring layer 223 and the separation conductive pattern 14 of the pixel separator DTI in the photoelectric conversion layer 150. Accordingly, the first connection structure 120 may be electrically connected to wirings in the wiring layer 200. The first connection line 121 may include a metal material, for example, tungsten. The light blocking pattern 48a may block light incident into the optical black area OB.

In one or more examples, the first conductive pad 81 may be provided inside the third trench TR3 to fill the remaining portion of the third trench TR3. The first conductive pad 81 may include a metal material, for example, aluminum. The first conductive pad 81 may be connected to the separation conductive pattern 14 of FIG. 4. A negative bias voltage may be applied to the separation conductive pattern 14 of the pixel separator DTI of FIG. 4 through the first conductive pad 81. Therefore, white spots or dark current problems may be advantageously prevented/reduced.

In one or more examples, the insulating pattern 123 may fill the remaining portion of the fourth trench TR4. The insulating pattern 123 may entirely or partially penetrate the photoelectric conversion layer 150 and the wiring layer 200. The first capping pattern 125 may be provided on an upper surface of the insulating pattern 123. The first capping pattern 125 may be provided on the insulating pattern 123.

The bulk color filter 90 may be provided on the first conductive pad 81, the light blocking pattern 48a, and the first capping pattern 125. The bulk color filter 90 may cover the first conductive pad 81, the light blocking pattern 48a, and the first capping pattern 125. A first protective layer 71 may be provided on the bulk color filter 90 to seal the bulk color filter 90.

A photoelectric conversion region PD′ and a dummy region PD″ may be provided in the optical black area OB of the first substrate 1. The photoelectric conversion region PD′ may be doped with, for example, impurities of a second conductivity type different from the first conductivity type. The second conductivity type may be, for example, n-type. The photoelectric conversion region PD′ may have a structure similar to that of the photoelectric converter PD, but may not perform the same operation as the photoelectric converter PD (e.g., operation of receiving light and generating an electrical signal). In one or more examples, the dummy region PD″ may not be doped with impurities. A signal generated in the dummy region PD″ may be used as information for removing process noise thereafter.

In the pad area PAD, a second connection structure 130, a second conductive pad 83, and a second protective layer 73 may be provided on the first substrate 1. The second connection structure 130 may include a second connection line 131, an insulating pattern 133, and a second capping pattern 135.

The second connection line 131 may be provided on the rear surface 1b of the first substrate 1. In one or more examples, the second connection line 131 may conformally cover the inner walls of a fifth trench TR5 and a sixth trench TR6 while covering the rear surface 1b. The second connection line 131 may pass through the photoelectric conversion layer 150 and the upper wiring layer 221 to connect the photoelectric conversion layer 150 and the wiring layer 200. In one or more examples, the second connection line 131 may be in contact with wirings in the lower wiring layer 223. Accordingly, the second connection structure 130 may be electrically connected to wiring in the wiring layer 200. The second connection line 131 may include a metal material, for example, tungsten.

The second conductive pad 83 may be provided inside the fifth trench TR5 to fill the remaining portion of the fifth trench TR5. The second conductive pad 83 may include a metal material, for example, aluminum. The second conductive pad 83 may serve as an electrical connection path to the outside of the image sensor device. The insulating pattern 133 may fill the remaining portion of the sixth trench TR6. The insulating pattern 133 may entirely or partially penetrate the photoelectric conversion layer 150 and the wiring layer 200. The second capping pattern 135 may be provided on the insulating pattern 133.

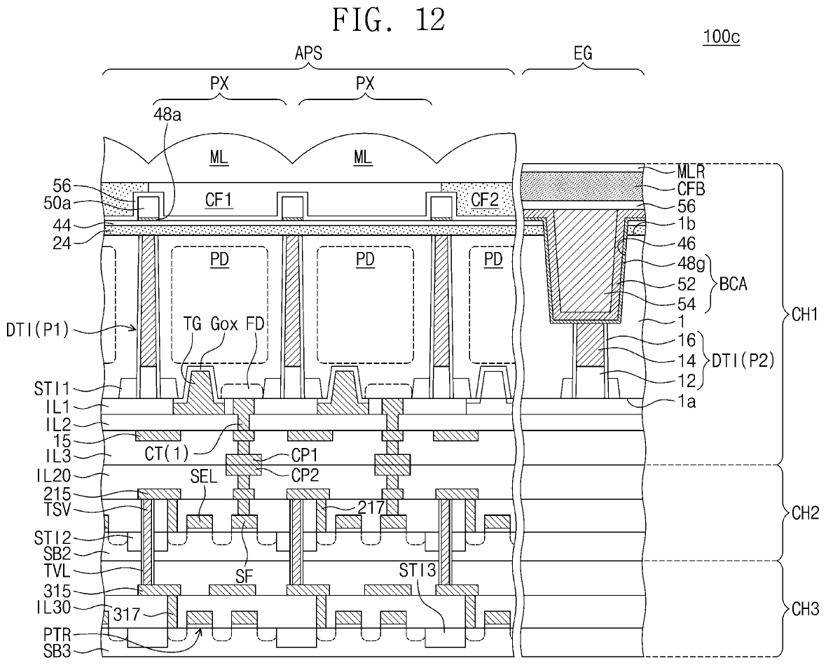

FIG. 12 is a cross-sectional view of an image sensor according to one or more embodiments of the present disclosure.

Referring to FIG. 12, an image sensor 100c, according to one or more examples, may have a structure in which first to third sub-chips CH1 to CH3 are sequentially bonded. The first sub-chip CH1 may, in one or more examples, perform an image sensing function. The first sub-chip CH1 may be the same as/similar to that described with reference to FIGS. 3 to 5B.

The first sub-chip CH1 may include transfer gates TG on a front surface 1a of a first substrate 1 and first to third interlayer insulating layers IL1 to IL3 covering the transfer gates TG. The first substrate 1 may include a pixel array area APS and an edge area EG. The pixel array area APS may include a plurality of unit pixels PX. The edge area EG may correspond to a portion of the optical black area OB of FIG. 8.

In one or more examples, a first device isolation part STI1 is disposed on the first substrate 1 to define active regions. A pixel separator DTI may be disposed on the first substrate 1 to separate/define the unit pixels PX from the pixel array area APS. The pixel separator DTI may extend to the edge region EG. The pixel separator DTI may be the same as/similar to that described with reference to FIG. 4.

In one or more examples, a front surface 1a of the first substrate 1 may be covered with first and second interlayer insulating layers IL1 and IL2. First to third contact plugs CT(1) to CT(3) described with reference to FIGS. 3 to 5B may be disposed in the first and second interlayer insulating layers IL1 and IL2. The second interlayer insulating layer IL2 may be covered with a third interlayer insulating layer IL3. First wiring 15 may be disposed in the third interlayer insulating layer IL3. A floating diffusion region FD may be connected to the first wiring 15 by the first contact plug CT(1). A first conductive pad CP1 may be disposed in the third interlayer insulating layer IL3. The first conductive pad CP1 may include copper.

In the edge region EG, a connection contact BCA may pass through a first protective layer 44, a fixed charge layer 24, and a portion of the first substrate 1 to be in contact with the separation conductive pattern 14. The connection contact BCA may be disposed in a third trench 46. The connection contact BCA may include a diffusion barrier pattern 48g conformally covering inner sidewalls and a bottom surface of the third trench 46, a first metal pattern 52 on the diffusion barrier pattern 48g, and a second metal pattern 54 filling the third trench 46. The diffusion barrier pattern 48g may include, for example, titanium. The first metal pattern 52 may include, for example, tungsten. The second metal pattern 54 may include aluminum, for example. The diffusion barrier pattern 48g and the first metal pattern 52 may extend on the first protective layer 44 and be electrically connected to other wirings or vias/contacts.

In one or more examples, a second protective layer 56 is stacked on the first protective layer 44. The second protective layer 56 may conformally cover the light blocking pattern 48a, the low refractive index pattern 50a, and the connection contact BCA.

In one or more examples, a first optical black pattern CFB may be disposed on the second protective layer 56 in the edge region EG. The first optical black pattern CFB may include, for example, the same material as a blue color filter.

In one or more examples, a lens residual layer MLR may be disposed on the first optical black pattern CFB in the edge region EG. The lens residual layer MLR may include the same material as the micro lenses ML.

The second sub-chip CH2 may include a second substrate SB2, select gate electrodes SEL on the second substrate SB2, source follower gate electrodes SF, reset gates, and a second chip interlayer insulating layers IL20 covering them. A second device isolation part STI2 is disposed on the second substrate SB2 to define active regions. Second contacts 217 and second wirings 215 may be disposed in the second chip interlayer insulating layers IL20. Second conductive pads CP2 may be disposed in an uppermost second chip interlayer insulating layers IL20. The second conductive pad CP2 may include copper. The second conductive pad CP2 may be in contact with the first conductive pad CP1. The source follower gates SF may be connected to the floating diffusion regions FD of the first sub-chip CH1, respectively.

In one or more examples, the third sub-chip CH3 may include a third substrate SB3, peripheral transistors PTR on the third substrate SB3, and third chip interlayer insulating layers IL30 covering them. A third device isolation part STI3 is disposed on the third substrate SB3 to define active regions. Third contacts 317 and third wirings 315 may be disposed in the third chip interlayer insulating layers IL30. An uppermost third chip interlayer insulating layers IL30 are in contact with the second substrate SB2. A through electrode TSV may penetrate the second interlayer insulating layer IL2, the second device isolation part STI2, the second substrate SB2, and the third chip interlayer insulating layers IL30 to connect a second wiring 215 and a third wiring 315. A sidewall of the through electrode TSV may be surrounded by a via insulation layer TVL. The third sub-chip CH3 may include circuits for driving the first and/or second sub-chips CH1 and CH2 or storing electrical signals generated by the first and/or second sub-chips CH1 and CH2.

In the semiconductor device and image sensor according to one or more embodiments of the present disclosure, the contact surface of the contact plug disposed in the first interlayer insulating layer and in contact with the substrate/gate electrode is wide, thereby reducing contact resistance, improving signal transmission speed, and reducing driving voltage. Since the dielectric constant of the first interlayer insulating layer is small, parasitic capacitance between contact plugs may be reduced. In addition, since the distance between ends of the contact plugs is increased, parasitic capacitance between the contact plugs may be reduced. Accordingly, it is possible to provide a semiconductor device and an image sensor having improved reliability by reducing signal interference.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims. The embodiments of FIGS. 3 through 12 can be combined with each other.

What is claimed is:

1. A semiconductor device comprising:
a gate pattern disposed on a substrate;
a first interlayer insulating layer on a sidewall of the gate pattern;
a second interlayer insulating layer on the gate pattern and the first interlayer insulating layer; and
a first contact plug passing through the second interlayer insulating layer and the first interlayer insulating layer and being in contact with the substrate,
wherein the first contact plug comprises a first contact part in the first interlayer insulating layer and a second contact part in the second interlayer insulating layer,
wherein the first contact part of the first contact plug has a first width, and
wherein the second contact part of the first contact plug has a second width smaller than the first width.

2. The semiconductor device of claim 1, wherein a porosity of the first interlayer insulating layer is greater than a porosity of the second interlayer insulating layer.

3. The semiconductor device of claim 1, further comprising an etch stop layer between a sidewall of the gate pattern and the first interlayer insulating layer and between the substrate and the first interlayer insulating layer,
wherein the first contact plug further comprises a third contact part penetrating the etch stop layer, and
wherein the third contact part of the first contact plug has a third width greater than the second width.

4. The semiconductor device of claim 1, wherein the gate pattern comprises a gate insulating layer, a gate electrode, and a gate capping pattern,
wherein the semiconductor device further comprises a second contact plug passing through the second interlayer insulating layer and the gate capping pattern,
wherein the second contact plug is in contact with the gate electrode,
wherein the second contact plug comprises a third contact part in the gate capping pattern and a fourth contact part in the second interlayer insulating layer,
wherein the third contact part of the second contact plug has a third width, and
wherein the fourth contact part of the second contact plug has a fourth width smaller than the third width.

5. The semiconductor device of claim 1, wherein the first contact plug further comprises a third contact part in the substrate, and
wherein the third contact part of the first contact plug has a third width smaller than the first width.

6. The semiconductor device of claim 1, wherein the first contact plug comprises a metal pattern and a diffusion barrier pattern on a sidewall of the metal pattern.

7. The semiconductor device of claim 1, wherein an upper surface of the first interlayer insulating layer is coplanar with an upper surface of the gate pattern.

8. An image sensor comprising:
a substrate including a plurality of pixels;
a first impurity region in the substrate in each of the pixels;
a first interlayer insulating layer on the substrate;
a second interlayer insulating layer on the first interlayer insulating layer; and
a first contact plug passing through the second interlayer insulating layer and the first interlayer insulating layer and being in contact with the substrate,
wherein the first contact plug comprises a first contact part in the first interlayer insulating layer and a second contact part in the second interlayer insulating layer,
wherein the first contact part of the first contact plug has a first width, and
wherein the second contact part of the first contact plug has a second width smaller than the first width.

9. The image sensor of claim 8, wherein a porosity of the first interlayer insulating layer is greater than a porosity of the second interlayer insulating layer.

10. The image sensor of claim 8, further comprising an etch stop layer between the substrate and the first interlayer insulating layer,
wherein the first contact plug further includes a third contact part penetrating the etch stop layer, and
wherein the third contact part of the first contact plug has a third width greater than the second width.

11. The image sensor of claim 8, further comprising:
a gate pattern on the substrate next to the first impurity region in each of the pixels and covered with the second interlayer insulating layer, the gate pattern comprising a gate insulating layer, a gate electrode, and a gate capping pattern; and
a second contact plug passing through the second interlayer insulating layer and the gate capping pattern, the second contact plug being in contact with the gate electrode,
wherein the second contact plug comprises a third contact part in the gate capping pattern and a fourth contact part in the second interlayer insulating layer;
wherein the third contact part of the second contact plug has a third width, and
wherein the fourth contact part of the second contact plug has a fourth width smaller than the third width.

12. The image sensor of claim 11, wherein an upper surface of the first interlayer insulating layer is coplanar with an upper surface of the gate pattern.

13. The image sensor of claim 11, wherein a first distance between an upper portion of the first contact plug and an upper portion of the second contact plug is greater than a second distance between a lower portion of the first contact plug and a lower portion of the second contact plug.

14. The image sensor of claim 8, wherein the first contact plug further comprises a third contact part in the substrate, and
wherein the third contact part of the first contact plug has a third width smaller than the first width.

15. The image sensor of claim 8, wherein the first contact plug comprises a metal pattern and a diffusion barrier pattern on a sidewall of the metal pattern.

16. An image sensor comprising:
a substrate comprising a plurality of pixels;
a floating diffusion region in the substrate in each of the pixels;
a first interlayer insulating layer on the substrate;
a second interlayer insulating layer on the first interlayer insulating layer;
a first contact plug passing through the second interlayer insulating layer and the first interlayer insulating layer and being in contact with the substrate;
a transfer gate pattern disposed on the substrate next to the floating diffusion region in each of the pixels and covered with the second interlayer insulating layer, the transfer gate pattern comprising a gate insulating layer, a gate electrode, and a gate capping pattern; and
a second contact plug passing through the second interlayer insulating layer and the gate capping pattern and being in contact with the gate electrode, and
wherein a first distance between an upper portion of the first contact plug and an upper portion of the second contact plug is greater than a second distance between a lower portion of the first contact plug and a lower portion of the second contact plug.

17. The image sensor of claim 16, wherein a first contact part of the first contact plug has a first width, and
wherein a second contact part of the first contact plug has a second width smaller than the first width.

18. The image sensor of claim 16, wherein a porosity of the first interlayer insulating layer is greater than a porosity of the second interlayer insulating layer.

19. The image sensor of claim 17, further comprising an etch stop layer interposed between the substrate and the first interlayer insulating layer,
wherein the first contact plug further comprises a third contact part penetrating the etch stop layer,
wherein the third contact part of the first contact plug has a third width greater than the second width.

20. The image sensor of claim 16, wherein the second contact plug comprises a third contact part in the gate capping pattern and a fourth contact part in the second interlayer insulating layer,
wherein the third contact part of the second contact plug has a third width, and
wherein the fourth contact part of the second contact plug has a fourth width smaller than the third width.
